(19) United States
(12) Patent Application Publication
(10) Pub. No.: US 2010/0207235 A1
(43) Pub. Date: Aug. 19, 2010

(54) SEMICONDUCTOR DEVICE AND METHOD FOR MANUFACTURING THE SAME

(76) Inventor: Woo Kyung SUN, Seoul (KR)

Correspondence Address: LADAS & PARRY LLP, 224 SOUTH MICHIGAN AVENUE, SUITE 1600, CHICAGO, IL, 60604, US

(21) Appl. No.: 12/421,206

(22) Filed: Apr. 9, 2009

(30) Foreign Application Priority Data
Feb. 16, 2009 (KR) 10-2009-0012420

(51) Int. Cl. H01L 29/06; H01L 21/762

(52) U.S. Cl. 257/506; 438/424; 257/E29.02; 257/E21.546

(57) ABSTRACT

A semiconductor device includes an isolation structure formed in a semiconductor substrate to delimit an active region. The active region includes a gate forming area. Spacers are formed on the side surfaces of the active region excluding portions of the side surfaces of the active region at the gate forming area, such that side surfaces of the gate forming area of the active region are exposed. A gate is formed to cover the exposed gate forming area of the active region.

### CROSS-REFERENCE TO RELATED APPLICATIONS

The present application claims priority to Korean patent application number 10-2009-0012420 filed on Feb. 16, 2009, which is incorporated herein by reference in its entirety.

### BACKGROUND OF THE INVENTION

The present invention relates generally to a semiconductor device and a method for manufacturing the same, and more particularly, to a semiconductor device which can ensure uniformity in the height of a fin pattern and improve the characteristics of a Is transistor and a method for manufacturing the same.

The recent and abrupt decrease in the design rule of highly integrated semiconductor devices has correspondingly resulted in both a decrease in the channel length and channel width of transistors and an increase in the doping concentrations of the source regions and drain regions of the semiconductor device. As a consequence, a junction leakage current increases due to the enhancement of electric fields. As such, it is difficult to obtain the required threshold voltage in a highly integrated semiconductor device when using transistors having a conventional planar channel structure, and limitations necessarily exist in improving refresh characteristics of the device. In light of these constraints, a gate having a three-dimensional channel structure capable of increasing a channel area has been pursued.

One example of a gate having a three-dimensional channel structure is the fin gate. The fin gate has a construction in which a fin pattern is formed by a protruding portion of the active region, and a gate line is formed to cover the fin pattern. The fin structure can increase the effective channel width; and therefore current drivability through a channel can be improved, and the threshold voltage margin can be increased.

However, fin gates are not without problems. For example, in a conventional fin gate, it is difficult to uniformly adjust the height of the fin pattern due to process limitations. In the fin gate, the current drivability and the operation characteristics of a transistor are dependent upon the height of the fin pattern. Therefore, the difficulties in acquiring a uniform height of the fin pattern can cause problems.

### SUMMARY OF THE INVENTION

Embodiments of the present invention include a semiconductor device which can ensure uniformity in the height of a fin pattern and a method for manufacturing the same.

Additionally, embodiments of the present invention include a semiconductor device that can improve the characteristics of a transistor and a method for manufacturing the same.

In one aspect of the present invention, a semiconductor device includes an isolation structure formed in a semiconductor substrate to delimit an active region, the active region including a gate forming area; spacers formed on side surfaces of the active region excluding portions of the side surfaces of the active region at the gate forming area such that side surfaces of the gate forming area of the active region are exposed; and a gate formed to cover the exposed gate forming area of the active region.

The exposed portions of the side surfaces in the gate forming area of the active region have a depth in the range of 100˜2,000 Å.

The spacers may comprise an insulation layer.

The insulation layer may comprise at least one of an oxide layer and a nitride layer.

The spacers may be formed to a thickness in the range of 10˜300 Å.

A portion of the thickness of the isolation structure may be etched in the gate forming area.

In another aspect of the present invention, a method for manufacturing a semiconductor device comprises the steps of etching a semiconductor substrate to define a first trench; forming spacers on sidewalls of the first trench; etching the semiconductor substrate at a bottoms of the first trench using the spacers as an etch mask to define a second trench; forming an isolation structure in the first and second trenches to delimit an active region, the active region having the spacers on side surfaces thereof; removing selectively portions of the spacers formed on side surfaces of a gate forming area of the active region such that the side surfaces of the gate forming area of the active region are exposed; and forming a gate to cover the exposed gate forming area of the active region.

The first trench may be defined to a depth in the range of 100˜2,000 Å.

The step of forming spacers comprises the steps of forming a layer for spacers on the semiconductor substrate including surfaces of the first trenches; and etching back the layer Is for spacers such that portions of the layer for spacers at the bottoms of the first trench are removed.

The layer for spacers may comprise an insulation layer.

The insulation layer may comprise at least one of an oxide layer and a nitride layer.

The layer for spacers may be formed to a thickness in the range of 10˜300 Å.

The step of removing selectively portions of the spacers such that the side surfaces of the gate forming area of the active region are exposed comprises the steps of forming a mask pattern on the resultant semiconductor substrate which is formed with the isolation structure, to expose a gate forming area; removing portions of the spacers exposed by the mask pattern; and removing the mask pattern.

When removing the exposed portions of the spacers, the isolation structure may be etched together with the exposed portions of the spacers by a partial thickness.

In still another aspect of the present invention, a method for manufacturing a semiconductor device comprises the steps of etching a semiconductor substrate to define a first trench; forming spacers on sidewalls of the first trenches; etching the semiconductor substrate at a bottoms of the first trench using the spacers as an etch mask to define a second trench; forming an isolation structure in the first and second trenches to delimit an active region, the active region having the spacers on side surfaces thereof; removing the spacers formed on side surfaces of the active region to expose the side surfaces of the active region; and forming a gate to cover the exposed side surfaces of the active region.

The first trench may be defined to a depth in the range of 100˜2,000 Å.

The step of forming spacers comprises the steps of forming a layer for spacers on the semiconductor substrate including surfaces of the first trench; and etching back the layer for spacers such that portions of the layer for spacers at the bottoms of the first trench are removed.

The layer for spacers may comprise an insulation layer.

The insulation layer may comprise at least one of an oxide layer and a nitride layer.

The layer for spacers may be formed to a thickness in the range of 10˜300 Å.

The step of removing the spacers to expose side surfaces of the active region comprises the steps of forming a mask pattern on the resultant semiconductor substrate which is formed with the isolation structure, to expose upper surfaces of the active region and the spacers; removing the spacers exposed by the mask pattern; and removing the mask pattern.

When removing the exposed spacers, the isolation structure is etched together with the exposed spacers by a partial thickness.

### BRIEF DESCRIPTION OF THE DRAWINGS

FIG. 1 is a plan view showing a semiconductor device in accordance with an embodiment of the present invention.

FIGS. 2A and 2B are cross-sectional views taken along the lines A-A′ and B-B′ respectively in FIG. 1, showing the semiconductor device in accordance with an embodiment of the present invention.

FIGS. 3A through 3G are cross sectional views taken along a line corresponding to the line A-A′ of FIG. 1, showing the processes of a method for manufacturing a semiconductor device in accordance with another embodiment of the present invention.

FIGS. 4A through 4G are cross-sectional views taken along a line corresponding to the line B-B′ of FIG. 1, showing the processes of the method for manufacturing a semiconductor device in accordance with another embodiment of the present invention.

FIGS. 5A through 5G are cross-sectional views taken along a line corresponding to the line A-A′ of FIG. 1, showing the processes of a method for manufacturing a semiconductor device in accordance with another embodiment of the present invention.

FIGS. 6A through 6G are cross-sectional views taken along a line corresponding to the line B-B′ of FIG. 1, showing the processes of the method for manufacturing a semiconductor device in accordance with another embodiment of the present invention.

### DESCRIPTION OF SPECIFIC EMBODIMENTS

In the present invention, spacers are formed on the side surfaces of the upper part of an active region, and then portions of the spacers formed in the gate forming area of the active region are removed to form a fin pattern exposing the side surfaces of the gate forming area of the active region. A gate is then formed in such a way as to cover the fin pattern. Accordingly, in the present invention, spacers can be formed on the side surfaces of the upper part of the active region having a height corresponding to that of the desired fin pattern, and then by removing the portions of the spacers formed in the gate forming area of the active region, the fin pattern is formed. As a result, in the present invention, uniformity in the height of the fin pattern can be ensured, and thereby the characteristics of a transistor can be improved.

Hereafter, specific embodiments of the present invention will be described with reference to the accompanying drawings.

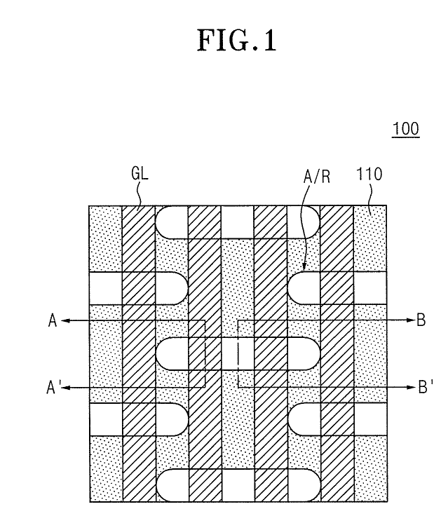

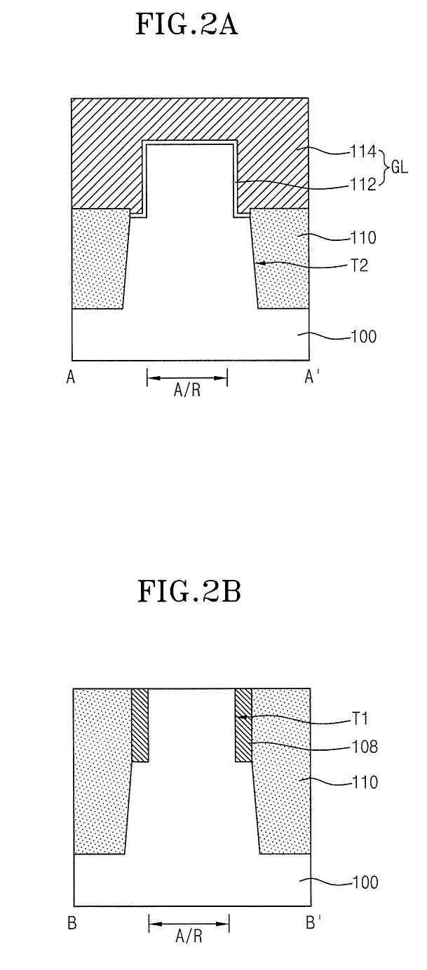

FIG. 1 is a plan view showing a semiconductor device in accordance with an embodiment of the present invention, and FIGS. 2A and 2B are cross-sectional views taken along the lines A-A′ and B-B′ respectively of FIG. 1.

Referring to FIGS. 2A and 2B, an isolation structure 110 is formed in a semiconductor substrate 100 to delimit an active region A/R. Spacers 108 are formed on the side surfaces of the area of the active region A/R with the exception of the portions of the side surfaces in a gate forming area, such that the side surfaces of the gate forming area of the active region A/R are exposed. That is, the active region A/R includes a gate forming area, and the spacers are formed to expose the side surfaces of the active region A/R in the gate forming area while being formed on the remaining area of the active region A/R.

The side surfaces of the gate forming area of the active region A/R are exposed at a depth extending in the range of, for example, 100˜2,000 Å below the upper surface of the active region A/R. The spacers 108 comprise, for example, an insulation layer such as an oxide layer and/or a nitride layer. The spacers 108 preferably comprise an oxide layer and are formed to a thickness in the range of, for example, 10˜300 Å when viewed from the cross-sectional view shown in FIG. 2B.

The portion of the isolation structure 110 in the gate forming area is etched by a partial thickness. A gate line GL is formed to cover the side surfaces of the gate forming area of the active region A/R exposed due to the non-formation of the spacers 108. The gate line GL comprises a gate insulation layer 112, a gate conductive layer 114, and a gate hard mask layer (not shown). The reference symbols T1 and T2 designate first and second trenches, respectively.

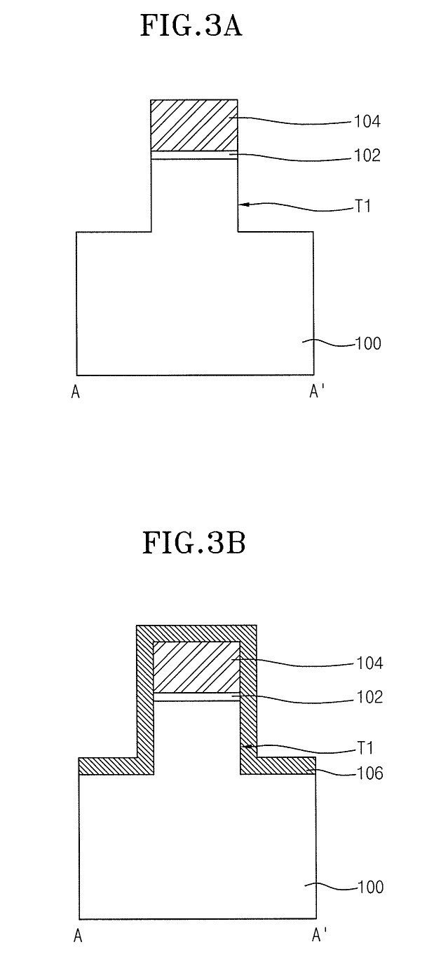

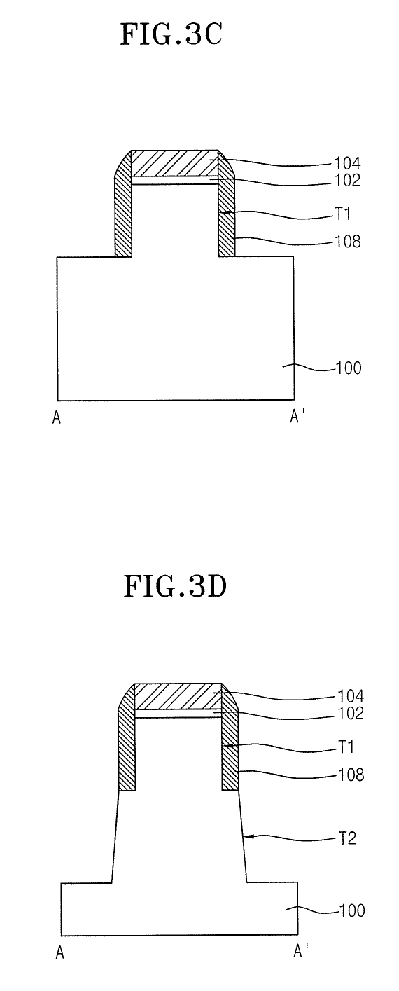

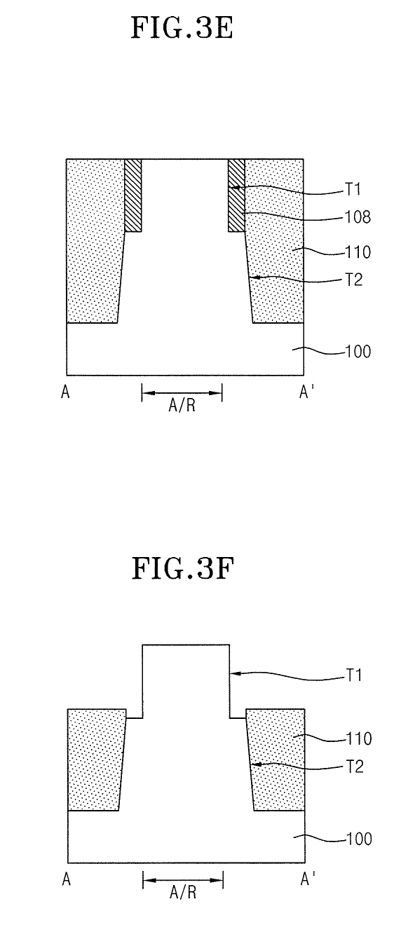

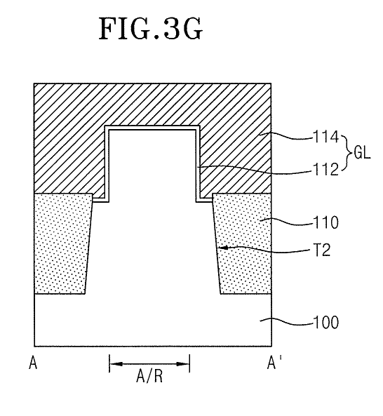

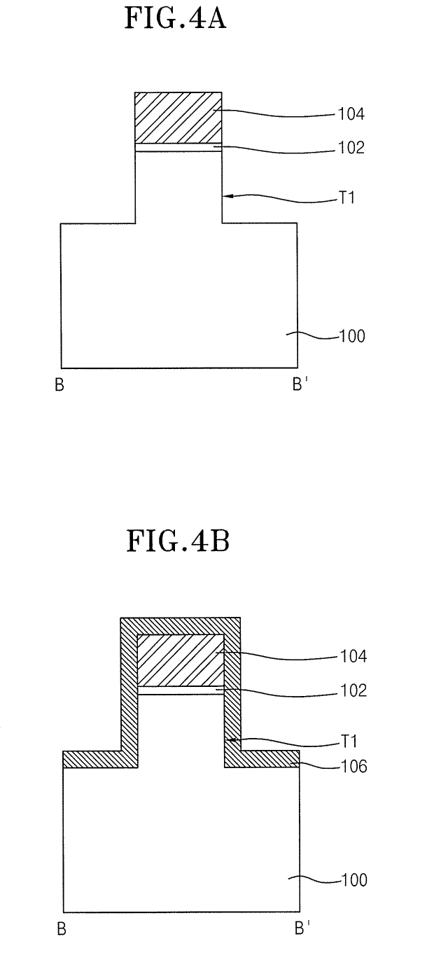

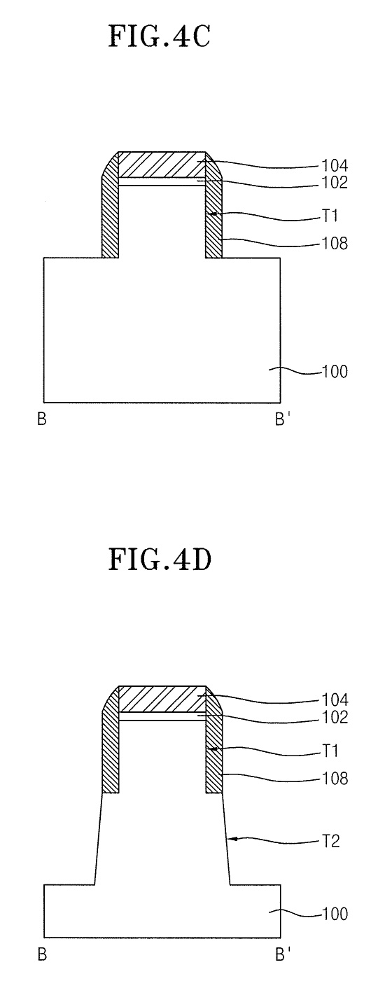

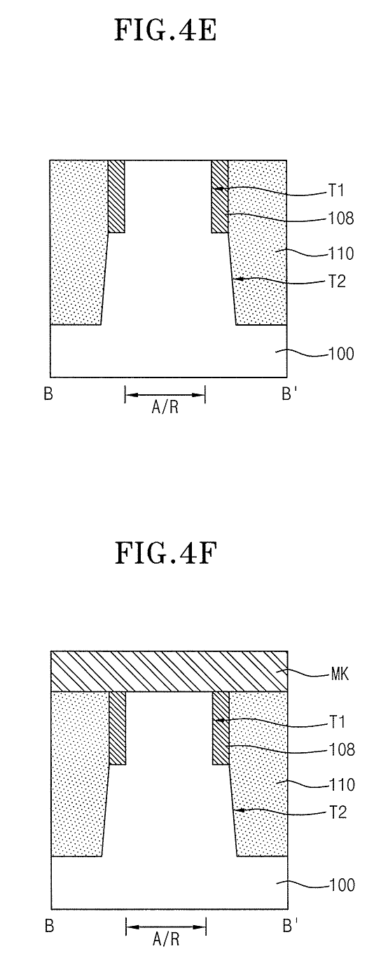

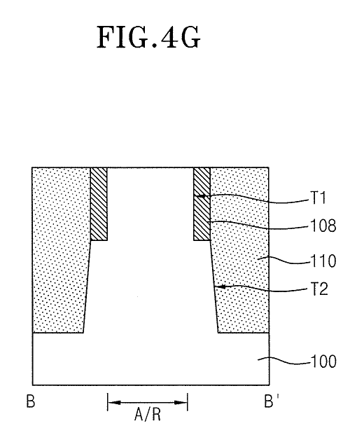

FIGS. 3A through 3G and 4A through 4G are cross-sectional views corresponding to the lines A-A′ and B-B′ of FIG. 1. FIGS. 3A through 3G and 4A through 4G show the processes of a method for manufacturing a semiconductor device in accordance with another embodiment of the present invention.

Referring to FIGS. 3A and 4A, a pad oxide layer 102 and a pad nitride layer 104 are sequentially formed on a semiconductor substrate 100. The pad nitride layer 104 is formed to have a thickness in the range of 500˜3,000 Å. Next, the pad nitride layer 104 and the pad oxide layer 102 are patterned to expose isolation regions of the semiconductor substrate 100, and thereafter the semiconductor substrate 100 is etched using the pad nitride layer 104 and the pad oxide layer 102 as an etch mask to define first a trench T1. Here, the first trench T1 is defined to have a depth corresponding to the desired height of a fin pattern, for example, of 100˜2,000 Å. In an embodiment of the present invention, the depth of the first trench T1 is defined to have a depth that is the same or substantially the same as the desired height of the fin pattern.

Referring to FIGS. 3B and 4B, a layer 106 for spacers is formed on the pad nitride layer 104 including on the surfaces of the trench T1. The layer 106 for spacers comprises, for example, an insulation layer such as an oxide layer and/or a nitride layer. The layer 106 for spacers preferably comprises an oxide layer and is formed to a thickness in the range of 10˜300 Å when viewed from the cross-section shown in FIGS. 3B and 4B.

Referring to FIGS. 3C and 4C, the layer 106 for spacers is etched back such that portions of the layer 106 for spacers are removed from the bottom of the first trench T1. As a result, spacers 108 are formed on the sidewalls of the first trench T1.

Referring to FIGS. 3D and 4D, the portions of the semiconductor substrate 100 that constitute the bottom of the first trench T1 are etched using the spacers 108 and the pad nitride layer 104 as an etch mask to define a second trench T2. At this time, a partial thickness of the pad nitride layer 104 may be etched together with the portions of the semiconductor substrate.

Referring to FIGS. 3E and 4E, an insulation layer for isolation is formed on the resultant semiconductor substrate 100 to fill the first and second trenches T1 and T2. The insulation layer for isolation comprises, for example, on oxide layer. The insulation layer is then chemically and mechanically polished (CMPed) to form an isolation structure 110 that delimits an active region A/R. Thereafter, the pad nitride layer 104 and the pad oxide layer 102 are removed. As a result, the upper surface of the active region A/R is exposed, and the spacers 108 are formed on the side surfaces of the upper part of the active region A/R as shown in FIG. 3E and FIG. 4E.

Referring to FIGS. 3F and 4F, a mask pattern MK is formed on the resultant semiconductor substrate 100 formed with the isolation structure 110 in such a way as to expose the gate forming area. The portions of the spacers 108 in the gate forming area, which are exposed through the mask pattern MK, are removed.

The removal of the portions of the spacers 108 is implemented through an etching process in which the etching selectivity of the insulation layer is set to be relatively high, as a result of which the portions of the spacers 108 formed of an insulation material and a partial thickness of the portions of the isolation structure 110 in the exposed gate forming area are etched together through the etching process. In the embodiment of the present invention in which the spacers 108 comprise an oxide layer, a dry etching process, in which the etching selectivity of the oxide layer with respect to silicon is set to be relatively high, can be conducted to remove the portions of the spacers 108 in the gate forming area. At this time, the dry etching process is conducted in a manner such that the etching selectivity between the silicon and the oxide layer becomes, for example, 1:3.5˜1:4.0. As a result, the portions of the spacers 108 (which comprise the oxide layer) and the partial thickness of the portions of the isolation structure 110 in the exposed gate forming area are etched together when conducting the dry etching process. Accordingly, as the portions of the spacers 108, which are formed on the side surfaces of the gate forming area of the active region A/R, are removed; the side surfaces of the gate forming area of the active region A/R are exposed.

Referring to FIGS. 3G and 4G, the mask pattern MK is removed. Then, a gate insulation layer 112 is formed on the side and upper surfaces of the gate forming area of the exposed active region A/R; and thereafter, a gate conductive layer 114 and a gate hard mask layer (not shown) are sequentially formed on the gate insulation layer 112. The gate hard mask layer, the gate conductive layer 114 and the gate insulation layer 112 are etched to form a gate line GL covering the exposed side and upper surfaces of the active region A/R at the gate forming area (i.e., the gate line GL covers the gate forming area of the active region A/R).

Thereafter, while not shown in the drawings, by sequentially conducting a series of well-known subsequent processes, the manufacture of the semiconductor device according to an embodiment of the present invention is completed.

As is apparent from the above description, in the embodiment of the present invention, a first trench is defined by a primary etching of a semiconductor substrate to a depth corresponding to a desired height of a fin pattern. Then, spacers are formed on the sidewalls of the first trench, and portions of the spacers on the gate forming area of the active region A/R are selectively removed to form a fin pattern in which the side and upper surfaces of the active region at the gate forming area (i.e., the side and upper surfaces of the gate forming area of the active region) are exposed.

Therefore, in the present invention, the fin pattern is formed in a manner such that portions of the semiconductor substrate are etched in advance to a depth corresponding to the desired height of the fin pattern; and therefore, the height of the fin pattern can be easily adjusted. Accordingly, in the present invention, uniformity in the height of the fin pattern can be ensured. Thus, in the present invention, the current drivability and operation characteristics of a transistor can be improved, whereby the characteristics and the reliability of a semiconductor device can be effectively improved.

In the aforementioned embodiment, the portions of the spacers formed in the gate forming area of the active region are selectively removed to form the fin pattern in which the side surfaces of the gate forming area of the active region are exposed. However, in another embodiment of the present invention, it is conceivable that, the spacers formed on the side surfaces of the active region can be entirely removed such that a fin pattern in which the entirety of the side surfaces of the active regions are exposed is formed.

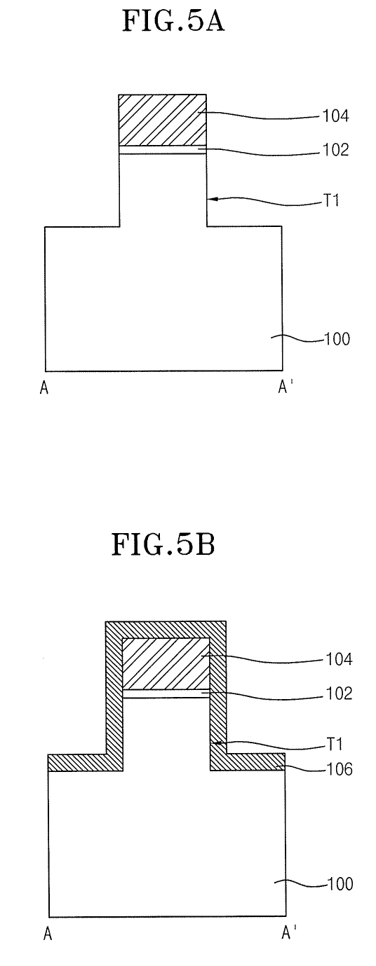

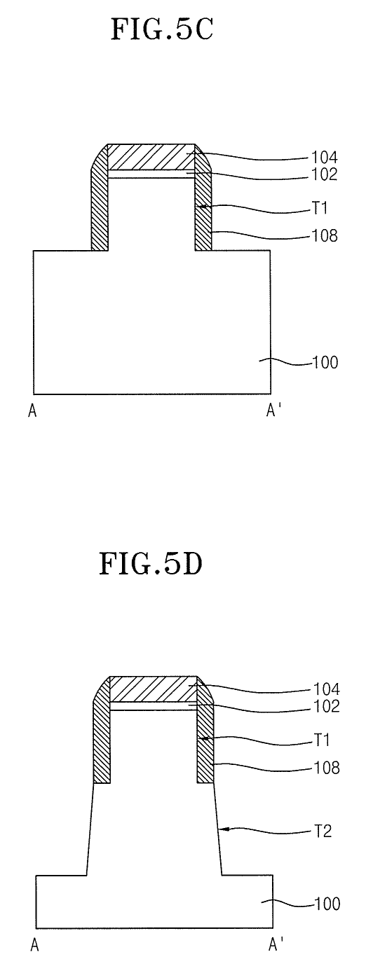

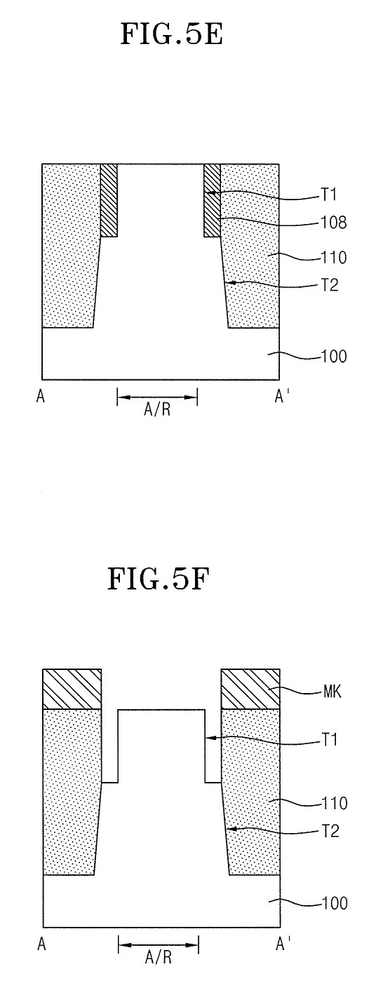

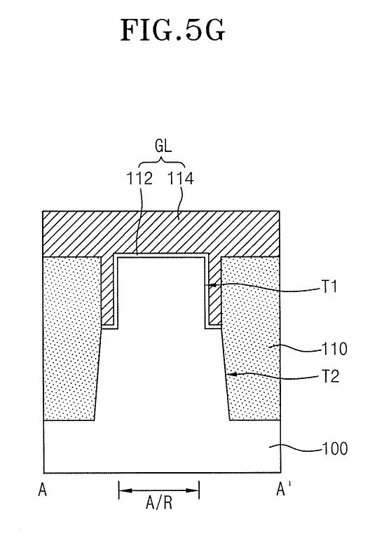

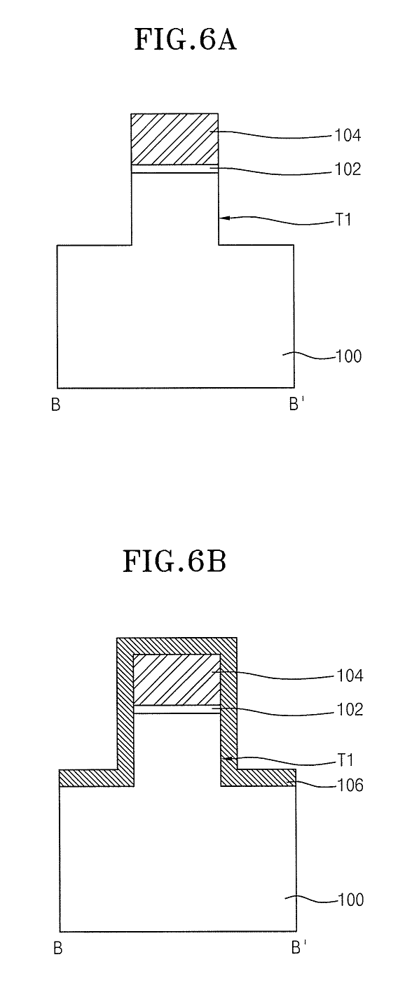

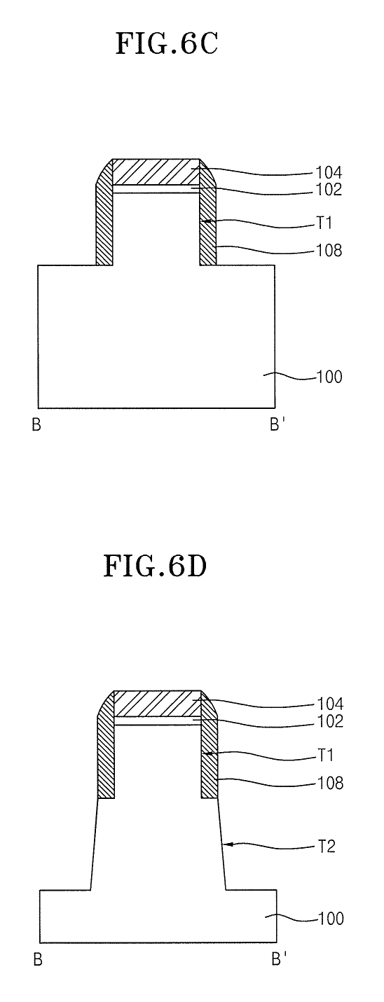

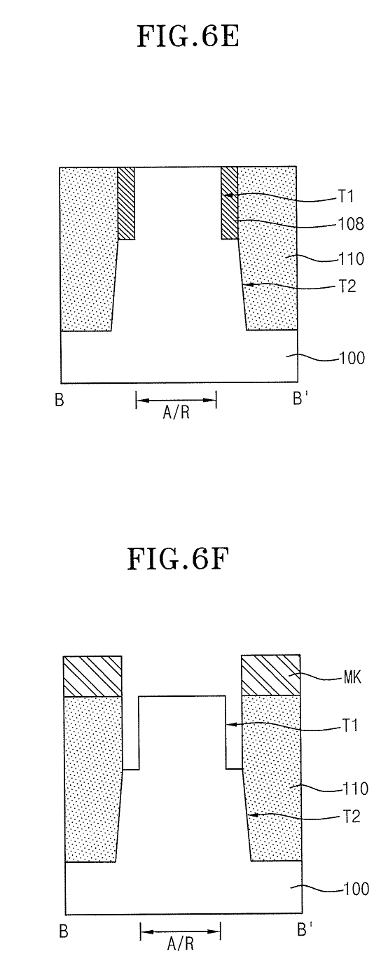

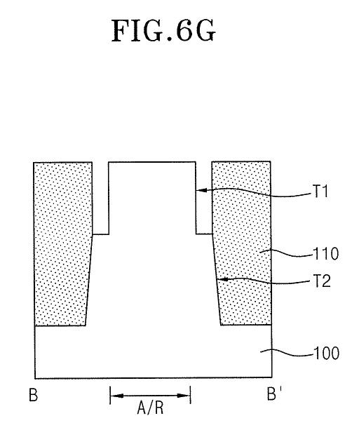

FIGS. 5A through 5G and 6A through 6G are cross-sectional views corresponding to the lines A-A′ and B-B′ of FIG. 1. FIGS. 5A through 5G and 6A through 6G show the processes of a method for manufacturing a semiconductor device in accordance with another embodiment of the present invention.

Referring to FIGS. 5A and 6A, a pad oxide layer 102 and a pad nitride layer 104 are sequentially formed on a semiconductor substrate 100. The pad nitride layer 104 is formed to a thickness in the range of 500˜3,000 Å. Next, the pad nitride layer 104 and the pad oxide layer 102 are patterned to expose isolation regions of the semiconductor substrate 100, and thereafter the semiconductor substrate 100 is etched using the pad nitride layer 104 and the pad oxide layer 102 as an etch mask to define a first trench T1 are defined. Here, the first trench T1 is defined to have a depth corresponding to the desired height of a fin pattern, for example, of 100˜2,000 Å. In an embodiment of the present invention, the depth of the first trench is defined to have a depth that is the same or substantially the same as the desired height of the fin pattern.

Referring to FIGS. 5B and 6B, a layer 106 for spacers is formed on the pad nitride layer 104 including on the surfaces of the trench T1. The layer 106 for spacers comprises, for example, an insulation layer such as an oxide layer and/or a nitride layer. The layer 106 for spacers preferably comprises an oxide layer and is formed to a thickness in the range of 10˜300 Å when viewed from the cross-section shown in FIGS. 5B and 6B.

Referring to FIGS. 5C and 6C, the layer 106 for spacers is etched back such that portions of the layer 106 for spacers are removed from the bottom of the first trench T1. As a result, spacers 108 are formed on the sidewalls of the first trench T1.

Referring to FIGS. 5D and 6D, the portions of the semiconductor substrate 100 that constitute the bottom of the first trench T1 are etched using the spacers 108 and the pad nitride layer 104 as an etch mask to define a second trench T2. At this time, a partial thickness of the pad nitride layer 104 may be etched together with the portions of the semiconductor substrate.

Referring to FIGS. 5E and 6E, an insulation layer for isolation is formed on the resultant semiconductor substrate 100 to fill the first and second trenches T1 and T2. The insulation layer for isolation comprises, for example, on oxide layer. Chemically and mechanically polishing (CMPing) is then performed on the insulation layer for isolation to form an isolation structure 110 that delimits an active region A/R. Thereafter, the pad nitride layer 104 and the pad oxide layer 102 are removed. As a result, the upper surface of the active region A/R is exposed, and the spacers 108 are formed on the side surfaces of the upper part of the active region A/R as shown in FIG. 5E and 6E.

Referring to FIGS. 5F and 6F, a mask pattern MK is formed on the resultant semiconductor substrate 100 formed with the isolation structure 110 in such a way as to expose the upper surfaces of the active region A/R and the spacers 108. The spacers 108, which are exposed through the mask pattern MK, are removed. Accordingly, as the spacers 108, which are formed on the side surfaces of the active region A/R, are removed, the side surfaces of the active region A/R are exposed.

The removal of the exposed spacers 108 is implemented through an etching process in which the etching selectivity of the insulation layer is set to be relatively high. For example, in an embodiment of the present invention in which the spacers 108 comprise an oxide layer, a dry etching process, in which the etching selectivity of the oxide layer with respect to silicon is set to be relatively high, is conducted to remove the spacers 108. The dry etching process is conducted in a manner such that the etching selectivity between the silicon and the oxide layer becomes, for example, 1:3.5˜1:4.0.

Meanwhile, although not shown in the drawings, it can be envisaged that, when removing the spacers 108, the mask pattern MK is not used and an etching process in which the etching selectivity of an insulation layer is set to be relatively high is conducted to remove the spacers 108 and a partial thickness of the portions of the isolation structure 110. Also, when the spacers 108 comprise a nitride layer, it can be envisaged that the mask pattern MK is not used and an etching process for selectively etching only the nitride layer is conducted to remove only the spacers 108.

Referring to FIGS. 5G and 6G, the mask pattern MK is removed. Then, a gate insulation layer 112 is formed on the side and upper surfaces of the exposed active region A/R and thereafter, a gate conductive layer 114 and a gate hard mask layer (not shown) are sequentially formed on the gate insulation layer 112. The gate hard mask layer, the gate conductive layer 114 and the gate insulation layer 112 are etched to form a gate line GL covering the exposed side and upper surfaces of the active region A/R at the gate forming area (i.e., the gate line GL covers the gate forming area of the active region A/R).

Thereafter, while not shown in the drawings, by sequentially conducting a series of well-known subsequent processes, the manufacture of the semiconductor device according to an embodiment of the present invention is completed.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device comprising:
an isolation structure formed in a semiconductor substrate to delimit an active region, the active region including a gate forming area;
spacers formed on side surfaces of the active region excluding portions of the side surfaces of the active region at the gate forming area, such that side surfaces of the gate forming area of the active region are exposed; and
a gate formed to cover the exposed gate forming area of the active region.

2. The semiconductor device according to claim 1, wherein the exposed portions of the side surfaces in the gate forming area of the active region have a depth in the range of 100˜2,000 Å.

3. The semiconductor device according to claim 1, wherein the spacers comprise an insulation layer.

4. The semiconductor device according to claim 3, wherein the insulation layer comprises at least one of an oxide layer and a nitride layer.

5. The semiconductor device according to claim 1, wherein a portion of the thickness of the isolation structure is etched in the gate forming area.

6. A method for manufacturing a semiconductor device, comprising the steps of:
etching a semiconductor substrate to define a first trench;
forming spacers on sidewalls of the first trench;
etching the semiconductor substrate at a bottom of the first trench using the spacers as an etch mask to define a second trench;
forming an isolation structure in the first and second trenches to delimit an active region, the active region having the spacers on side surfaces thereof;
removing selectively portions of the spacers formed on side surfaces of a gate forming area of the active region such that the side surfaces of the gate forming area of the active region are exposed; and
forming a gate to cover the exposed gate forming area of the active region.

7. The method according to claim 6, wherein the first trench is defined to a depth in the range of 100˜2,000 Å.

8. The method according to claim 6, wherein the step of forming spacers comprises the steps of:
forming a layer for spacers on the semiconductor substrate including surfaces of the first trench; and
etching back the layer for spacers such that portions of the layer for spacers at the bottom of the first trench are removed.

9. The method according to claim 8, wherein the layer for spacers comprises an insulation layer.

10. The method according to claim 9, wherein the insulation layer comprises at least one of an oxide layer and a nitride layer.

11. The method according to claim 6, wherein the step of removing selectively portions of the spacers such that the side surfaces of the gate forming area of the active region are exposed comprises the steps of:
forming a mask pattern on the resultant semiconductor substrate which is formed with the isolation structure, to expose a gate forming area;
removing portions of the spacers exposed by the mask pattern; and
removing the mask pattern.

12. The method according to claim 11, wherein, when removing the exposed portions of the spacers, the isolation structure is etched together with the exposed portions of the spacers by a partial thickness.

13. A method for manufacturing a semiconductor device, comprising the steps of:
etching a semiconductor substrate to define a first trench;
forming spacers on sidewalls of the first trench;
etching the semiconductor substrate at a bottom of the first trench using the spacers as an etch mask to define a second trench;
forming an isolation structure in the first and second trenches to delimit an active region, the active region having the spacers on side surfaces thereof;
removing the spacers formed on side surfaces of the active region to expose the side surfaces of the active region; and
forming a gate to cover the exposed side surfaces of the active region.

14. The method according to claim 13, wherein the first trench is defined to a depth in the range of 100˜2,000 Å.

15. The method according to claim 13, wherein the step of forming spacers comprises the steps of:
forming a layer for spacers on the semiconductor substrate including surfaces of the first trench; and
etching back the layer for spacers such that portions of the layer for spacers at the bottom of the first trench are removed.

16. The method according to claim 15, wherein the layer for spacers comprises an insulation layer.

17. The method according to claim 16, wherein the insulation layer comprises at least one of an oxide layer and a nitride layer.

18. The method according to claim 13, wherein the step of removing the spacers to expose side surfaces of the active region comprises the steps of:
forming a mask pattern on the resultant semiconductor substrate which is formed with the isolation structure, to expose upper surfaces of the active region and the spacers;
removing the spacers exposed by the mask pattern; and
removing the mask pattern.

19. The method according to claim 18, wherein, when removing the exposed spacers, the isolation structure is etched together with the exposed spacers by a partial thickness.
